(19) United States
(12) Patent Application Publication
(10) Pub. No.: US 2011/0176118 A1
(43) Pub. Date: Jul. 21, 2011

(54) ELECTRONIC APPARATUS

(75) Inventors: Tsung Hsun Wu, Taoyuan County (TW); Wen-Chung Ho, Taoyuan County (TW); Chih-Heng Tsao, Taoyuan County (TW)

(73) Assignee: QISDA CORPORATION, Taoyuan (TW)

(21) Appl. No.: 13/005,554

(22) Filed: Jan. 13, 2011

(30) Foreign Application Priority Data
Jan. 18, 2010 (TW) 099101188

(51) Int. Cl. G03B 21/16; H05K 7/20

(52) U.S. Cl. 353/61; 361/692

(57) ABSTRACT

An electronic apparatus comprising a casing forming a first inflow entrance and an outflow exit, the first inflow entrance allowing entry of a first airflow, the outflow exit allowing exit of a second airflow ; a light source module disposed in the casing; and a blower disposed in the casing, the blower having an outer wall, a blower flow inlet, a flow exit; a PCB disposed in the casing, the PCB having a heat-generation element, a first flow-conduit being formed between the outer wall and the PCB, and the a heat-generation element being located at the first flow-conduit; wherein, as heat ventilation is performed in the electronic apparatus, the first airflow is introduced into the blower flow inlet via the first flow-conduit, and an airflow exiting from the flow exit is directed to exit the casing from the outflow exit after taking heat from light source module.

### CROSS-REFERENCE TO RELATED APPLICATION

This utility application claims priority to Taiwan Application Serial 099101188, filed Jan. 18, 2010, which is incorporated herein by reference.

### BACKGROUND OF THE INVENTION

1. Field of the invention

The invention relates to an electronic apparatus, for instance a projector, having novel design of cooling system.

2. Description of the prior art

Recently, the projection apparatuses which usually are commodities in the corporate market also are becoming the commodities in the household market for family entertainment use. For different applications of projection apparatuses, the volume size and the cooling capability are always important issues which need to tackle.

In the state of arts, the pico-type (or portable) projectors typically use heat-sink fins and isolation materials along with air layers within the projectors to isolate the heat, or distribute the internal heat sources as uniform as possible within the casing of projector in order to achieve better cooling operation. Other implementations, e.g. the axial-type fans, are utilized as well to fulfill the required cooling functions. It is known that a design of higher brightness in projector would proportionally increase the heat generated. It have been found that the conventional approaches fail to cool the projector effectively while the projection brightness increases to as high as 50 Lumen (Lm, the SI unit of luminous flux).

Therefore, there is a need for a corresponding cooling system in the pico projector which has a higher brightness design.

### SUMMARY OF THE INVENTION

A main objective of the invention is to provide an effective cooling capability for an electronic apparatus, e.g. pico projection apparatus.

To achieve the objective, the embodiment of invention is an electronic apparatus which includes a casing, a light source module disposed in the casing, a blower, a PCB disposed within the casing, and which can effectively lower the operation temperature of electronic apparatus.

The casing forms a first inflow entrance and an outflow exit, the first inflow entrance allows flow-in of a first airflow, and the outflow exit allows flow-out of a second airflow.

The blower is disposed within the casing, the blower has an outer wall, a blower flow inlet and blower flow outlet.

The PCB is disposed within the casing and has at least a heat-generation element, the outer wall of blower and the PCB form a first flow-conduit, the heat-generation element is located on the first flow-conduit.

As the electronic apparatus is undergoing the cooling operation, the first airflow, via the first flow-conduit, enters the blower flow inlet, and an airflow is outputted from the blower flow outlet to cool the light source module and flow out of the casing from the outflow exit.

In one embodiment, the casing has a front-side and a back-side opposite to the front-side, a left-side and a right-side respectively connected to the front-side, and a second inflow entrance. The front-side is provided with the outflow exit, the right-side is provided with the first inflow entrance, the left-side is provided with the second inflow entrance, the outer wall along with the PCB forms a second flow-conduit. As the electronic apparatus undergoes cooling operation, a third airflow, via the second flow-conduit, enters the blower flow inlet.

According to another embodiment, the electronic apparatus further includes a battery module, the casing includes a third inflow entrance provided on the back-side. As the electronic apparatus undergoes cooling operation, a fourth airflow, via the third inflow entrance, flows through the battery module taking the generated heat away and enters the blower flow inlet.

According to another embodiment, the blower is located between the light source module and the battery module, and the third inflow entrance is a slot for receiving a memory card.

According to another embodiment, airflow direction flowing into the blower flow inlet is about perpendicular to airflow direction flowing out of the blower flow outlet. In one embodiment, the electronic apparatus has a single blower, and according to one preferred embodiment, the electronic apparatus is a projector for projecting desired image or information onto a surface. According to another embodiment, the light source module at least includes a light source of first kind and a corresponding first heat sink.

Under the core inventive spirit recited above, more specific embodiments can be realized by referring to the additional descriptions in the following detailed descriptions and dependent claims.

### BRIEF DESCRIPTION OF THE APPENDED DRAWINGS

Each illustrated embodiment of the present invention will be fully understood with reference to the following description in details and the attached drawings.

FIG. 1 discloses a projector according to the preferred embodiment of the invention.

FIG. 2 shows sectional view of the projector in FIG. 1 along the sectional-line A-A.

FIG. 3 shows the projector in FIG. 1 in perspective view and the airflows therein.

### DETAILED DESCRIPTION OF THE INVENTION

The following exemplary embodiments of the present invention will be further described with reference to the attached drawings. While the present invention has been described with reference to exemplary embodiments, it is to be understood that various changes and modifications may be made and the invention is not limited to the disclosed exemplary embodiments that are use to enable persons skilled in the art to practice the present invention.

The electronic apparatus of invention might be in form of a projector apparatus which is for projecting an image onto a surface for people to view the content within the image. The projector apparatus may constitute a standalone projector or may be in modular form integrating another portable apparatus, such as a mobile phone, to become a portable multiple-function apparatus, such as a mobile phone with the pico projector function.

In the following recitations, terms like first, second, third, fourth etc. are used to label elements, e.g. airflow or entrance, for distinction purpose. It is to be understood that there is no implication about the order or sequence between those labeled elements. For instance, the first airflow does not happen before the second airflow, and it might be the case that the first airflow and the second airflow happen substantially simultaneously. This general principle applies to all label elements.

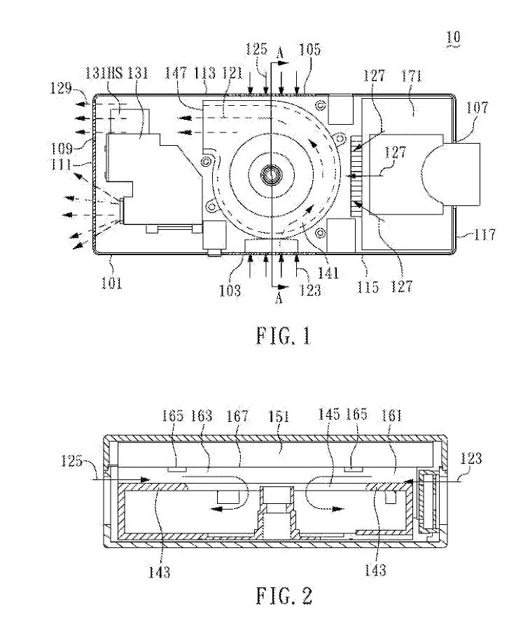

FIG. 1 shows the top view of electronic apparatus 10 according to an embodiment of the invention. FIG. 2 shows sectional view of the projector in FIG. 1 along the sectional-line A-A to illustrate the blower, its relationship with neighboring elements, and the airflows generated. In addition to conventional or other elements, the electronic apparatus 10 includes a casing 101, a light source module 131, a blower 141 and a PCB 151 (shown in FIG. 2). The casing 101 is provided with an first inflow entrance 103 for indraft of an airflow 123 and an outflow exit 109 for exiting of an airflow 129. The light source module 131 and the blower 141 are respectively disposed within the casing 101. The blower 141 has an outer wall 143 (shown in FIG. 2), a blower flow inlet 145 (shown in FIG. 2) and a blower flow outlet 147. The PCB 151 is disposed within the casing 101 and has at least one heat-generation element 165 thereon. The outer wall 143 and the PCB 151 form a first flow-conduit 161 and the heat-generation element 165 is located and exposed to the first flow-conduit 161. As the electronic apparatus 10 is in a mode undergoing cooling operation, the blower 141 is activated and the airflow 123, via the first flow-conduit 161, enters the blower flow inlet 145. In succession, the airflow 121 is outputted from the blower flow outlet 147 to take the heat away from the light source module 131, and then the airflow 129 containing the heat flows out of the casing 101 from the outflow exit 109.

In an embodiment, the electronic apparatus 10 only has a single blower 141. And the airflow direction flowing into the blower flow inlet 145 (the vertical downward direction in FIG. 2) is substantially perpendicular to the airflow direction flowing out of the blower flow outlet 147 (the direction indicated by the airflow 129 in FIG. 1). In an embodiment, the electronic apparatus 10 is a projector for projecting an image onto a surface for people to view the content within the image.

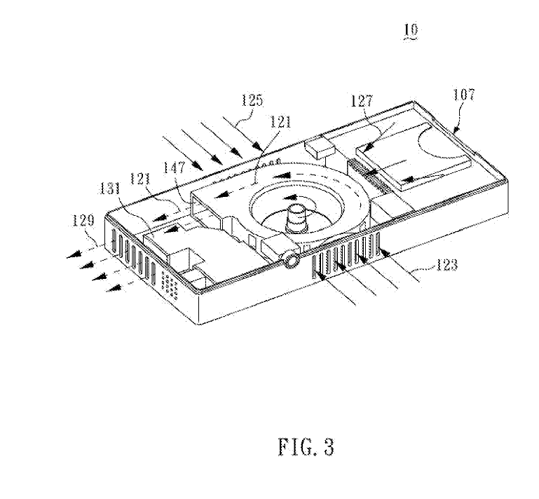

Under the configuration shown in FIG. 1, in some embodiments, the light source module 131 includes a light source of first kind (e.g. LED light source) and a corresponding first heat sink 131HS. As the airflow 121 flows through the first heat sink 131HS and takes heat away from it, the airflow 129 flows out of the casing 101 via the outflow exit 109. The first heat sink 131HS is shown in FIG. 1, and, however, in FIG. 3, the first heat sink 131HS is not shown to avoid obstruction to other elements.

FIG. 2 shows sectional view of the projector in FIG. 1 along the sectional-line A-A to illustrate the blower, its relationship with neighboring elements, and the airflows generated.

By the illustration of FIGS. 1 and 2, it is observed that the casing 101 includes a front-side 111, a back-side 117 opposite to the front-side 111, a left-side 113 and a right-side 115 respectively connected to the front-side 111. For application of a projector, the front-side 111 is provided with the outflow exit 109 and has an opening allowing the projection image to go through. The right-side 115 is provided with the first inflow entrance 103, the left-side 113 is provided with the second inflow entrance 105, and the outer wall 143 along with PCB 151 forms a second flow-conduit 163. As the electronic apparatus 10 undergoes cooling operation, an airflow 125, via the second flow-conduit 163, enters the blower flow inlet 145 as well.

In a preferred embodiment, the outer wall 143 neighboring the blower flow inlet 145 and heat-generation plane 167 of PCB 151 form the first conduit 161 and the second 163. On the heat-generation plane 167, there is at least one heat-generation element 165 which might be control IC chips, resistor elements, inductance elements, for instance.

According to one embodiment, the electronic apparatus 10 further includes a battery module 171 (second heat-generation element) for supplying power to the electronic apparatus 10. The casing 101 has a third inflow entrance 107 provided on the back-side 117. As the electronic apparatus 10 undergoes cooling operation, an airflow 127, through the third inflow entrance 107, flows over the battery module 171 and enters the blower flow inlet 145.

According to one embodiment, the blower 141 is located between the light source module 131 and the battery module 171, and the third inflow entrance 107 is a slot for receiving a memory card, as indicated in FIG. 1.

According to one embodiment, one surface of PCB 151 and the outer wall 143 form the first flow-conduit 161, and this surface of PCB 151 faces toward the blower flow inlet 145, as indicated in FIG. 2.

According to one embodiment, the airflow direction flowing into the blower flow inlet 145 (the vertical downward direction in FIG. 2) is substantially perpendicular to the airflow direction (the direction of airflow 129 in FIG. 1, or the outward direction from plane of FIG. 2 to observer) flowing out of the blower flow outlet 147.

FIG. 3 shows the projector in FIG. 1 in perspective view and the airflows therein. Specifically, the flowing directions of the airflow 123, the airflow 125, the airflow 127, the airflow 121 and the airflow 129 are shown. From the above descriptions of preferred embodiments and the appended drawings, it is believed that airflow flowing-path design of the invention provides better cooling operation efficiency, a reduced operating temperature and an assured operation safety.

While the present invention has been shown and described with reference to the preferred embodiments thereof and in terms of the illustrative drawings, it should not be interpreted as limited thereby. Various possible modifications and alterations could be conceived of by one skilled in the art to the form and the content of any particular embodiment, without departing from the scope and the spirit of the present invention. Such modifications or alternations are also the scope the following claims intend to cover.

What is claimed is:

1. An electronic apparatus, comprising:
a casing forming a first inflow entrance and an outflow exit, the first inflow entrance allowing flow-in of a first airflow, the outflow exit allowing flow-out of a second airflow;
a light source module disposed within the casing;
a blower disposed within the casing, the blower having an outer wall, a blower flow inlet and blower flow outlet; and
a PCB disposed within the casing, the PCB having a heat-generation element, the outer wall and the PCB forming a first flow-conduit, the heat-generation element being located on the first flow-conduit;
wherein, as the electronic apparatus is undergoing cooling operation, the first airflow, via the first flow-conduit, enters the blower flow inlet, an airflow is outputted from the blower flow outlet to cool the light source module and flow out of the casing from the outflow exit.

2. The electronic apparatus of claim 1, wherein the casing has a front-side and a back-side in respect to the front-side, a left-side and a right-side respectively connected to the front-side, and a second inflow entrance, the front-side is provided with the outflow exit, the right-side is provided with the first inflow entrance, the left-side is provided with the second inflow entrance, the outer wall along with the PCB forms a second flow-conduit, as the electronic apparatus undergoes cooling operation, a third airflow, via the second flow-conduit, enters the blower flow inlet.

3. The electronic apparatus of claim 2, wherein further comprising battery module, the casing includes a third inflow entrance provided on the back-side, as the electronic apparatus undergoes cooling operation, a fourth airflow, via the third inflow entrance, flows through the battery module and enters the blower flow inlet.

4. The electronic apparatus of claim 3, wherein the blower is located between the light source module and the battery module, and the third inflow entrance is a slot for receiving a memory card.

5. The electronic apparatus of claim 1, wherein the PCB has a plane, the plane and the outer wall together form the first flow-conduit, and the plane faces towards the blower flow inlet.

6. The electronic apparatus of claim 1, wherein airflow direction flowing into the blower flow inlet is about perpendicular to airflow direction flowing out of the blower flow outlet.

7. The electronic apparatus of claim 1, wherein further comprises a battery module, and the blower is disposed between the light source module and the battery module.

8. The electronic apparatus of claim 1, wherein the electronic apparatus only has a single blower.

9. The electronic apparatus of claim 1, wherein the electronic apparatus is a projector.

10. The electronic apparatus of claim 1, wherein the light source module at least includes a light source of first kind and a corresponding first heat sink.

11. A projector, comprising:
a casing forming a first inflow entrance and an outflow exit, the first inflow entrance allowing flow-in of a first airflow, the outflow exit allowing flow-out of a second airflow;
a light source module disposed within the casing;
a blower disposed within the casing, the blower having an outer wall, a blower flow inlet and blower flow outlet; and
a PCB disposed within the casing, the PCB having a first heat-generation element, the outer wall and the PCB forming a first flow-conduit, the first heat-generation element being located on the first flow-conduit;
wherein, as the electronic apparatus is undergoing cooling operation, the first airflow, via the first flow-conduit, enters the blower flow inlet, an airflow is outputted from the blower flow outlet to cool the light source module and flow out of the casing from the outflow exit.

12. The projector of claim 11, wherein the casing has a front-side and a back-side opposite to the front-side, a left-side and a right-side respectively connected to the front-side, and a second inflow entrance, the front-side is provided with the outflow exit, the right-side is provided with the first inflow entrance, the left-side is provided with the second inflow entrance, the outer wall along with the PCB forms a second flow-conduit, as the projector undergoes cooling operation, a third airflow, via the second flow-conduit, enters the blower flow inlet.

13. The projector of claim 11, further comprising a second heat-generation element, wherein the casing has a front-side and a back-side opposite to the front-side, a left-side and a right-side respectively connected to the front-side, one of the right-side and the left-side is provided with the first inflow entrance, the casing includes a second inflow entrance provided on the back-side, as the projector undergoes cooling operation, a third airflow, via the second inflow entrance, flows through the second heat-generation element and enters the blower flow inlet, the direction of the first airflow is different from the direction of the second airflow.

14. The projector of claim 13, wherein the second heat-generation element is a battery module and the blower is located between the light source module and the battery module, and the third inflow entrance is a slot for receiving a memory card.

15. The projector of claim 11, wherein the PCB has a plane, the plane and the outer wall together form the first flow-conduit, and the plane faces towards the blower flow inlet.

16. The projector of claim 11, wherein further comprises a battery module, and the blower is disposed between the light source module and the battery module.

17. A projector, comprising:
a casing forming a first inflow entrance and an outflow exit, the first inflow entrance allowing flow-in of a first airflow, the outflow exit allowing flow-out of a second airflow;
a light source module disposed within the casing;
a single blower disposed within the casing, the blower having an outer wall, a blower flow inlet and blower flow outlet; and
a PCB disposed within the casing, the PCB having a heat-generation element, the outer wall and the PCB forming a first flow-conduit, the heat-generation element being located on the first flow-conduit;
wherein, as the electronic apparatus is undergoing cooling operation, the first airflow, via the first flow-conduit, enters the blower flow inlet, an airflow is outputted from the blower flow outlet to cool the light source module and flow out of the casing from the outflow exit.

18. The projector of claim 17, wherein the casing has a front-side and a back-side in respect to the front-side, a left-side and a right-side respectively connected to the front-side, and a second inflow entrance, the front-side is provided with the outflow exit, the right-side is provided with the first inflow entrance, the left-side is provided with the second inflow entrance, the outer wall along with the PCB forms a second flow-conduit, as the projector undergoes cooling operation, a third airflow, via the second flow-conduit, enters the blower flow inlet.

19. The projector of claim 17, further comprising battery module, the casing includes a second inflow entrance, as the projector undergoes cooling operation, a third airflow, via the second inflow entrance, flows through the battery module and enters the blower flow inlet.

20. The projector of claim 17, wherein further comprises a battery module, and the blower is disposed between the light source module and the battery module.
